(19) United States
(12) Patent Application Publication
(10) Pub. No.: US 2013/0300254 A1
(43) Pub. Date: Nov. 14, 2013

(54) PIEZOELECTRIC DEVICE AND METHOD OF MANUFACTURING THE SAME, AND ELECTRONIC DEVICE MANUFACTURING METHOD

(71) Applicant: FUJIFILM CORPORATION, (US)

(72) Inventors: Takamichi FUJII, Kanagawa (JP); Akihiro MUKAIYAMA, Kanagawa (JP)

(73) Assignee: FUJIFILM CORPORATION, Tokyo (JP)

(21) Appl. No.: 13/837,420

(22) Filed: Mar. 15, 2013

(30) Foreign Application Priority Data
Mar. 22, 2012 (JP) 2012-065739

(51) Int. Cl. H01L 41/047; H01L 41/33

(52) U.S. Cl. CPC H01L 41/047; H01L 41/33
USPC 310/317; 29/25.35

(57) ABSTRACT

A piezoelectric device includes: a substrate; a lower electrode provided on a substrate; a piezoelectric film provided by being laminated on the lower electrode, the piezoelectric film being formed of lead zirconate titanate (PZT) containing 6 at % or more in atomic composition percentage of at least one type of metal element selected from V group and VI group; an oxide electrode layer provided by being laminated on the piezoelectric film; a first metal electrode layer containing an oxidation-resistant precious metal provided by being laminated on the oxide electrode layer; a second metal electrode layer provided by being laminated on the first metal electrode layer; and a wire connected to the second metal electrode layer.

### BACKGROUND OF THE INVENTION

1. Field of the Invention

The presently disclosed subject matter relates to a piezoelectric device and a method of manufacturing the piezoelectric device and, in particular, relates to a structure and manufacturing technologies of a device that operates by using a piezoelectric effect and inverse piezoelectric effect of a piezoelectric film such as an actuator, an acceleration sensor or am angular velocity sensor, and manufacture technologies of an electronic device having a piezoelectric device mounted thereon.

2. Description of the Related Art

Piezoelectric actuators and piezoelectric sensors using a piezoelectric film made of lead zirconate titanate (PZT) or the like have been widely known (refer to Japanese Patent Application Laid-Open No. 2009-123974, Japanese Patent Application Laid-Open No. 2009-244202, Japanese Patent Application Laid-Open No. 2010-249713, Japanese Patent Application Laid-Open No. 2006-308291, and Japanese Patent Application Laid-Open No. 11-083500). Japanese Patent Application Laid-Open No. 2009-123974 describes a problem in which decreased polarization (also referred to as “depolarization”) occurs in a piezoelectric material due to a heating process such as solder reflow in a process of manufacturing an electronic device including the piezoelectric device to degrade piezoelectric performance (paragraph 0005 to 0006 of Japanese Patent Application Laid-Open No. 2009-123974). Japanese Patent Application Laid-Open No. 2009-123974 suggests a composition and stress of a piezoelectric film for obtaining an element not undergoing decreased polarization by a heating process and excellent in heat resistance, and a polarization process method of such the piezoelectric film.

Japanese Patent Application Laid-Open No. 2009-244202 discloses a manufacturing method of obtaining many angular velocity sensors having a desired piezoelectric characteristic from one silicon substrate (wafer). Japanese Patent Application Laid-Open No. 2009-244202 suggests the manufacturing method of performing a resistance inspection on each of many angular velocity sensors formed on a substrate and efficiently performing a polarization process only on an angular velocity sensor determined as a conforming item.

Japanese Patent Application Laid-Open No. 2010-249713 describes a method of manufacturing an angular velocity sensor element using a piezoelectric thin film, and discloses a structure in which a film made of either one of Ti and W and Au is formed as an upper electrode (paragraphs 0013 and 0025). Japanese Patent Application Laid-Open No. 2010-249713 also describes that DC (direct-current) voltage of approximately 20 V is applied between upper and lower electrodes interposing the piezoelectric film to make polarization vectors uniform (paragraph 0031). Note that the structure of the upper electrode made of a laminated layer of a Ti layer and an Au layer is also disclosed in Japanese Patent Application Laid-Open No. 2009-244202, paragraph 0053 and Japanese Patent Application Laid-Open No. 2006-308291, paragraph 0029.

Japanese Patent Application Laid-Open No. 11-083500 discloses a structure in which a resin silver conductor (a phenol resin with silver particles dispersed) is used as a material of an electrode formed after a polarization process on a piezoelectric substance (PZT) and this material is cured at a temperature lower than the Curie temperature of PZT to form the electrode (paragraph 0052). In the structure described in Japanese Patent Application Laid-Open No. 11-083500, it is considered that the characteristics of the piezoelectric substance are degraded (polarization is destroyed) if heating is performed at a temperature equal to the Curie temperature or higher.

### SUMMARY OF THE INVENTION

As described in the patent gazettes described above, a polarization process is conventionally required for a piezoelectric film. Moreover, if the conventional PZT or other material is subjected to a solder reflow process or the like after a device is made, depolarization (decreased polarization) occurs in the piezoelectric film, and therefore a processing process such as reflow is required to be performed at a temperature as low as possible to minimize a decrease in characteristic of the piezoelectric substance or a re-polarization process is required to be performed after a high-temperature process such as reflow.

FIG. 13 and FIG. 14 are flowcharts of a conventional process of manufacturing an electronic device using a piezoelectric film (PZT). FIG. 13 is a flow in which reflow is performed after a polarization process, and FIG. 14 is a flow in which a polarization process is performed after reflow.

In the example of FIG. 13, after a lower electrode is formed on a silicon (Si) substrate (steps S210 to S212), a PZT film is formed on the lower electrode for patterning to a desired shape (step S214). On the PZT film, an upper electrode is formed and patterned to form a target laminated structure (step S216), and then the silicon layer is processed so as to have a desired shape and thickness (step S218). Then, a polarization process is performed (step S220) to achieve a required polarization state. After the polarization process, isolation is performed by dicing from a wafer to individual element units (step S222), a connection is made to an integrated circuit by wire bonding (step S224), and then packaging is performed (step S226). The packaged device is implemented on an electronic circuit board, and a solder reflow process is performed (step S228). With this, an electronic circuit board having the device mounted thereon is fabricated, and then a final product (an electronic device) is manufactured after an assembling process (step S230).

In FIG. 14, processes identical or similar to those in the flow described with reference to FIG. 13 are provided with the same step number. In the example of FIG. 14, after an implementing/reflow/assembling process depicted as step S228, a polarization process is performed (step S229), and then a final product (an electronic device) is obtained (step S230).

In the pattern of FIG. 13, contrivances are required such as using a piezoelectric material with a Curie point as high as possible, making a device with an implementing method without performing reflow, or decreasing the reflow temperature as low as possible. Moreover, when no polarization process is performed after reflow, problems can be occurred such as piezoelectric performance is degraded at the time of reflow and variations in reflow temperature directly lead to variations in performance of the element.

By contrast, with the pattern of FIG. 14, since a polarization process has to be performed in the final process, it is cumbersome to perform a process on each chip one by one. In practice, it is extremely difficult to perform a polarization process after reflow.

In view of these viewpoints, the inventors of the present application have studied a manufacturing process without performing a polarization process, got an idea of using a piezoelectric film allowing a predetermined polarization state to be obtained without performing a polarization process, and verified its applicability. An Nb-doped PZT film has a feature in which its piezoelectric constant is already excellent in a state without being subjected to a polarization process (in a non-polarized state) (Japanese Patent Application Laid-Open No. 2011-078203). This material is not easily depolarized even if heated, and therefore easy to handle without restrictions on temperature in processes after film formation.

However, a tendency has been observed when the inventors of the present application tried to fabricate a piezoelectric device using this piezoelectric material such that, if a heating process such as solder reflow is performed after a device is made by forming an upper electrode on a piezoelectric film superposed on a lower electrode, although depolarization does not occur in the piezoelectric materials, permittivity is increased by approximately 10% (capacitance is changed). The permittivity increased by the heating process is decreased by applying a high voltage between the lower electrode and the upper electrode to perform a polarization process (a re-polarization process) and to become closer to an original value (i.e., the permittivity before the heating process). Even if this re-polarization process is performed, however, the permittivity cannot be completely returned to the original value before the heating process. For this reason, this increase causes variations in design and performance of the element. This is a new problem not conventionally known, and its cause has not yet been found.

The presently disclosed subject matter was made in view of these circumstances and with attention to the new problem described above. An object of the presently disclosed subject matter is to provide a highly-reliable piezoelectric device with small changes in capacitance of an element even after a heating process such as reflow and with ensured stable performance. Another object of the presently disclosed subject matter is to provide a method of manufacturing the piezoelectric device described above and a method of manufacturing an electronic device having the piezoelectric device mounted thereon.

To achieve the objects described above, a piezoelectric device according to the presently disclosed subject matter includes a substrate, a lower electrode provided on a substrate, a piezoelectric film provided by being laminated on the lower electrode, the piezoelectric film being formed of lead zirconate titanate (PZT) containing 6 at % or more in atomic composition percentage of at least one type of metal element selected from the V group and the VI group, an oxide electrode layer provided by being laminated on the piezoelectric film, a first metal electrode layer containing an oxidation-resistant precious metal provided by being laminated on the oxide electrode layer, a second metal electrode layer provided by being laminated on the first metal electrode layer, and a wire connected to the second metal electrode layer by wire bonding, and the piezoelectric device operates by using at least one of a piezoelectric effect and an inverse piezoelectric effect of the piezoelectric film.

The upper electrode is configured of the oxide electrode layer, the first metal electrode layer, and the second metal electrode layer. The oxide electrode layer inhibits oxygen from being drawn from the piezoelectric film, and functions as an adhesive layer. The first metal electrode layer functions as an oxygen blocking layer, and plays a role of increasing adhesiveness with the second metal electrode layer. The second metal electrode layer is a layer for connection with a wire by wire bonding, and a material suitable for wire bonding is used.

Note that, in interpretation of terms, a representation “B is laminated on A” not only means that B is directly laminated on A so that B is in contact with A but also can mean that B is laminated on A via one or a plurality of layers.

Other aspects of the presently disclosed subject matter become apparent from the description of the specification and the drawings.

According to the presently disclosed subject matter, it is possible to obtain a piezoelectric device not requiring a polarization process, with small changes in capacitance of an element even after a heating process such as reflow and with ensured stable performance.

### BRIEF DESCRIPTION OF THE DRAWINGS

FIG. 1 is a schematic sectional view of the structure of main parts of a piezoelectric device according to an embodiment of the presently disclosed subject matter;

FIG. 2 is a diagram of an example of bipolar polarization-electric field hysteresis (P-E hysteresis) of a piezoelectric film;

FIG. 3 is a table of experiment results obtained by examining bias ratios of piezoelectric films with different Nb amounts and whether a polarization process is required;

FIG. 4 is a table of conditions and evaluation results of samples of Examples 1 to 4 and Comparative Examples 1 to 7;

FIG. 5 is a table of conditions and evaluation results of a sample using an intrinsic PZT;

FIG. 6 is a plan view of an example of structure of the piezoelectric device according to the embodiment of the presently disclosed subject matter;

FIG. 7 is a side view of the piezoelectric device according to the embodiment;

FIG. 8 is a cross-sectional view along a B-B line in FIG. 6;

FIG. 9 is a block diagram of an example of structure of a drive detection circuit;

FIG. 10 is a schematic view of an example of structure of a sensor device having an angular velocity sensor and an ASIC (application specific integrated circuit) packaged therein;

FIG. 11 is a flowchart of a process of manufacturing a piezoelectric device according to the present embodiment and an electronic device having the piezoelectric device mounted thereon;

FIGS. 12A-12G are diagrams for describing a process of manufacturing the piezoelectric device;

FIG. 13 is a flowchart of a first example of a conventional process of manufacturing an electronic device having a piezoelectric device mounted thereon; and

FIG. 14 is a flowchart of a second example of the conventional process of manufacturing an electronic device having a piezoelectric device mounted thereon.

### DETAILED DESCRIPTION OF THE EMBODIMENTS

Embodiments of the presently disclosed subject matter are described in detail below according to the attached drawings.

### Embodiment

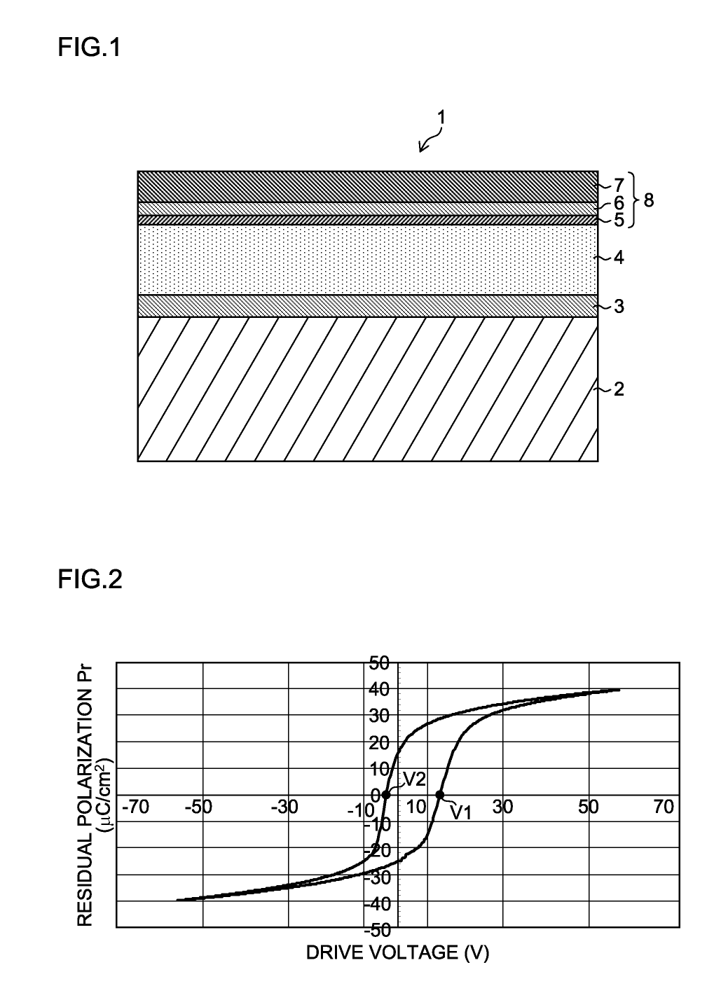

FIG. 1 is a schematic sectional view of a structure of main parts of a piezoelectric device according to an embodiment of the presently disclosed subject matter. As depicted in FIG. 1, a piezoelectric device 1 of the present example is configured as a laminated structure formed by laminating a lower electrode 3 and a piezoelectric film 4 (in this example, a Nb-doped PZT film is used) in this order on a substrate 2 made of silicon (Si) or the like serving as a support layer, laminating an oxide electrode layer 5 on the piezoelectric film 4, laminating an oxidation-resistant first metal electrode layer 6 on the oxide electrode layer 5, and then further laminating a second metal electrode layer 7 suitable for wire bonding on the first metal electrode layer 6.

Note that the film thickness of each layer depicted in FIG. 1 and other drawings and their ratio are drawn with changes as appropriate for convenience of description, and do not necessarily reflect the actual film thickness and ratio. Also, in the specification, for representation of the laminated structure, a direction away from the surface of the substrate 2 in a substrate thickness direction is referred to as an “upward direction”. Since the structure in FIG. 1 is such that the lower electrode 3 and each of the other layers (3 to 7) are sequentially laminated on an upper surface of the substrate 2 with the substrate 2 being horizontally held, the relation matches with a vertical relation when a direction of gravity (downward in FIG. 1) is taken as a downward direction. However, the posture of the substrate 2 can be tilted or reversed. For representation of the vertical relation of the laminated structure without confusion even when the laminating direction of the laminated structure depending on the posture of the substrate 2 does not match with the vertical direction with reference to the direction of gravity, a direction away from a surface of the substrate 2 as a reference in a thickness direction is hereinafter represented as an “upward direction”. For example, even if FIG. 1 is flipped vertically, representation is made such that the lower electrode 3 is formed on the substrate 2 and the piezoelectric film 4 is laminated on the lower electrode 3.

The material of the substrate 2 is not particularly restrictive and, for example, any of silicon (Si), silicon oxide, glass, stainless (SUS (Steel Use Stainless)), yttria-stabilized zirconia (YSZ), alumina, sapphire, SiC, and SrTiO₃ can be used. Also, as the substrate 2, a laminated substrate such as a SOI (Silicon on Insulator) substrate having a SiO₂ film and a Si active layer sequentially laminated on a silicon substrate may be used.

The composition of the lower electrode 3 is not particularly restrictive, and examples of the composition of the lower electrode 3 can include metals such as Au (gold), Pt (platinum), Ag (silver), Ir (iridium), Al (aluminum), Mo (molybdenum), Ru (ruthenium), TiN (titanium nitride), IrO₂, RuO₂, LaNiO₃, and SrRuO₃, metal oxides of these metals, and combinations thereof. In particular, the lower electrode 3 preferably has a structure containing a metal in Platinum Group Metals. Also, to improve adhesiveness to the substrate 2, a structure using Ti or TiW as an adhesive layer is preferable, and a further preferable mode is such that a platinum group metal is laminated on this adhesive layer to form the lower electrode 3.

As the piezoelectric film 4, a piezoelectric film formed of one type or a plurality of types of perovskite-type oxide represented by the following general formula (P-1) is used (which may contain inevitable impurities).

Pbₐ(Zr_{b1}Ti_{b2}X_{b3})O₃ (P-1)

(in the formula (P-1), X is at least one of metal element selected from element groups of the V group and the VI group; a>0, b1>0, b2>0, b3>0; while a≧1.0 and b1+b2+b3=1.0 as a standard, these numerical values may include a tolerance from 1.0 as long as a perovskite structure can be taken).

The perovskite-type oxide represented by the general formula (P-1) is lead zirconate titanate (PZT) when b3=0, and an oxide with part of the B site of PZT substituted by at least one type of metal element selected from element groups of the V group and the VI group when b3>0.

X may be any one of metal elements of the VA group, the VB group, the VIA group, and the VIB group, and is preferably at least one type selected from the group including V, Nb, Ta, Cr, Mo, and W.

[Regarding Film Forming Method]

As a method of forming the piezoelectric film 4, chemical vapor deposition is preferable. For example, in addition to sputtering, any of various methods can be applied, such as ion plating, MOCVD (metal-organic chemical vapor deposition), and PLD (pulse laser deposition). Also, a method other than chemical vapor deposition (for example, sol-gel method) can be used.

In the present embodiment, an example of using a PZT film doped with Nb is described. In the following, the piezoelectric film 4 may be referred to as an “Nb-doped PZT film”. On the Nb-doped PZT film (the piezoelectric film 4), the upper electrode 8 having the laminated structure of the oxide electrode layer 5, the oxidation-resistant first metal electrode layer 6, and the second metal electrode layer 7 suitable for wire bonding is formed. That is, the upper electrode 8 has the laminated structure in which the oxide electrode layer 5 of a first layer placed at an interface with the piezoelectric film 4, the oxidation-resistant first metal electrode layer 6 of a second layer, and the second metal electrode layer 7 of a third layer. Each of the layers (5 to 7) included in the upper electrode 8 has a role as described below.

The oxide electrode layer 5 of the first layer is placed on an interface with the piezoelectric film 4, and the oxide electrode layer 5 plays a role of preventing oxygen from being drawn from the Nb-doped PZT film. Also, since the Nb-doped PZT film is an oxide and the oxide electrode layer 5 is also an oxide, these layers have excellent adhesiveness due to lamination of these oxide and oxide, and the oxide electrode layer 5 functions as an adhesive layer. As the oxide electrode layer 5, for example, any one of ITO, LaNiO, IrOₓ, RuOₓ, and PtOₓ can be used (where x representing a composition ratio is any number equal to 1 or more).

Note that Ti or the like is often used as an electrode layer provided on an interface with a conventional PZT (intrinsic PZT not doped with Nb) film. However, since Ti is easily oxidized, it becomes an insulator even if it is thin, disadvantageously affecting piezoelectric driving and sensing. Moreover, oxygen is drawn from PZT when Ti is oxidized, causing the piezoelectric characteristics of PZT to be easily changed. These problems do not occur in the oxide electrode layer 5 in the present embodiment.

As the second layer of the upper electrode 8, the first metal electrode layer 6 resistant to oxidation is provided so as to be superposed on the oxide electrode layer 5 of the first layer. This first metal electrode layer 6 plays a role of blocking oxygen diffused from the oxide electrode layer 5 and the piezoelectric film 4 (inhibiting movement of oxygen atoms) and keeping adhesiveness with the second metal electrode layer 7. As the “metal resistant to oxidation (oxidation-resistant metal)” for use as the first metal electrode layer 6, any one of precious metals such as Ir, Pt, Ru, and Pd is preferable.

Also, another preferable structure is such that an oxide of Ir, Ru, or others is used as the first layer and the same metal as the first layer (Ir, Ru, or others) is used as the second layer. Furthermore, the first layer and the second layer may be successively (seamlessly) formed in a manner such that a metal oxide is formed in reactive gas by chemical vapor deposition and a metal is formed in a state with the reactive gas drained. For example, a film of an oxide of Ir (IrOₓ where x is any number equal to 1 or more) and a film of Ir can be seamlessly formed.

The second metal electrode layer 7 of the third layer is a layer for electric connection with an ASIC (Application Specific Integrated Circuit) and other electronic circuit (including a lead wiring pattern) by using wire bonding and anisotropic conductive film (ACF). For this purpose, this third layer is required to be a material excellent in wire bonding. As a condition, a metal with a relatively low melting point is preferable. As a guideline, a metal with a melting point equal to 1500 degrees Celsius or lower is desirable. For example, the second metal electrode layer 7 preferably has a structure containing any one of Al, Au, Ti, Cu, Cr, and Ni.

While the thickness of each of the layers (denoted by reference numerals 5 to 7) included in the upper electrode 8 is not particularly restrictive, the oxide electrode layer 5 (the adhesive layer) of the first layer and the oxidation-resistant metal electrode layer (the first metal electrode layer 6 or an oxygen blocking layer) of the second layer preferably have a thickness of 5 nm (nanometers) or more, preferably 10 nm or more.

The second metal electrode layer 7 of the third layer is preferably thick because of wire bonding, and preferably has a thickness of 50 nm or more. However, if the thickness is too thick, adhesiveness is possibly degraded. Therefore, the second metal electrode layer 7 preferably has a thickness of 1000 nm or less.

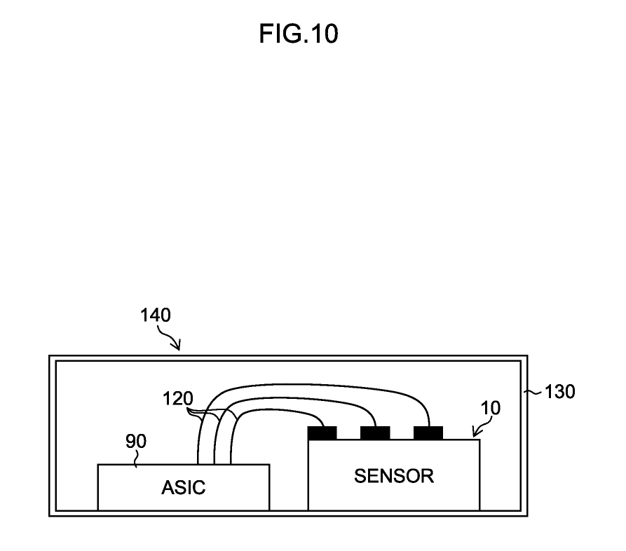

Although not depicted in FIG. 1, the second metal electrode layer 7 of the uppermost layer is connected via a wire (a bonding wire denoted by a reference numeral 120 in FIG. 10) not illustrated to an electronic circuit (not illustrated in FIG. 1 and denoted by a reference numeral 90 in FIG. 10).

<Regarding Characteristics of Piezoelectric Film>

FIG. 2 depicts bipolar polarization-electric field hysteresis (P-E hysteresis) of the piezoelectric film 4. The horizontal axis of FIG. 2 represents drive voltage (electric field), and the vertical axis represents polarization. The drive voltage is represented by the product of the thickness of the piezoelectric film in a voltage applying direction and the electric field, and an electric field value can be obtained by dividing the drive voltage value by the thickness of the piezoelectric substance. “V1” in FIG. 2 is the product of a coercive electric field Ec1 on a positive field side and the thickness of the piezoelectric film in the voltage applying direction, and “V2” is the product of a coercive electric field Ec2 on a negative field side and the thickness of the piezoelectric film in the voltage applying direction.

As depicted in FIG. 2, the Nb-doped PZT film has a P-E hysteresis characteristic having coercive electric field points on the negative field side and the positive field side and asymmetrical with respect to the y axis representing polarization. In FIG. 2, the coercive electric field Ec1 on the negative field side and the coercive electric field Ec2 on the positive field side has a relation of |Ec1|<Ec2. In the asymmetrical P-E hysteresis thus biased to the positive field side, the coercive electric field Ec2 is large when a positive electric field is applied, and therefore the film is less prone to polarization. When a negative electric field is applied, the absolute value of the coercive electric field Ec1 is small, and therefore the film is prone to polarization.

When the “bias ratio” of the P-E hysteresis is defined by the following [Equation 1], the bias ratio of the P-E hysteresis depicted in FIG. 2 is approximately 76%.

[Equation 1]

(Ec2+Ec1)/(Ec2−Ec1)×100(%) (1)

As such, the piezoelectric film 4 with a P-E hysteresis curve biased to right (to the positive field side) as a whole is previously polarized in a state where a polarization process is not performed.

The value calculated from [Equation 1] represents the “bias ratio” because the P-E hysteresis characteristic is biased to the positive field side in the present embodiment.

Conversely, in the case of a piezoelectric substance having P-E hysteresis characteristics biased to the negative field side, the bias ratio is an absolute value of the value obtained from [Equation 1].

<Regarding Nb Dope Amount, Bias Ratio, and Whether Polarization Process is Required>

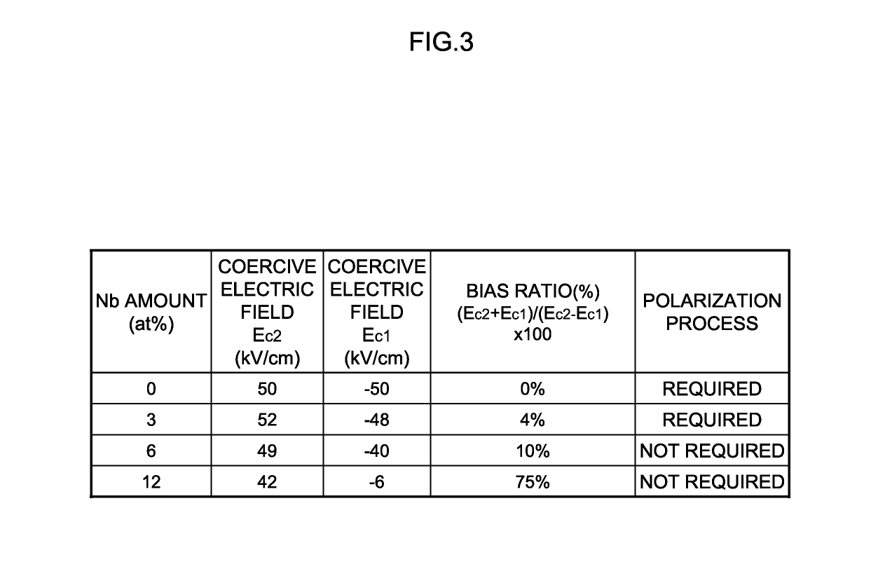

The bias ratio has a correlation with the Nb dope amount. FIG. 3 is a table of experiment results obtained by examining bias ratios of piezoelectric films with different Nb amounts and whether a polarization process is required. The Nb amount is represented by atomic composition percentage (at %). An Nb amount of “0” indicates intrinsic PZT not doped with Nb. As described in the table, it can be found that a polarization process is not required with the bias ratio is 10% or more, that is, the Nb amount is 6 [at %] or more.

An upper limit of the Nb amount can be determined in view of whether a piezoelectric film suitable for practice can be formed. In general, piezoelectric performance is improved as the Nb dope amount is increased. However, if the Nb dope amount is excessively large, a crack tends to occur in relation to stress. If the film thickness is thin, a crack tends not to occur. Therefore, the Nb dope amount is determined also depending on the film thickness of the piezoelectric film to be actually used. In the case of a piezoelectric actuator or a piezoelectric sensor assumed to be applied to a general electronic device, the upper limit of the Nb amount is approximately on the order of 20%. That is, the Nb dope amount of the piezoelectric film 4 is preferably 6 at % or more and 20 at % or less.

By using this piezoelectric material, a polarization process conventionally required is not required.

### EXAMPLES

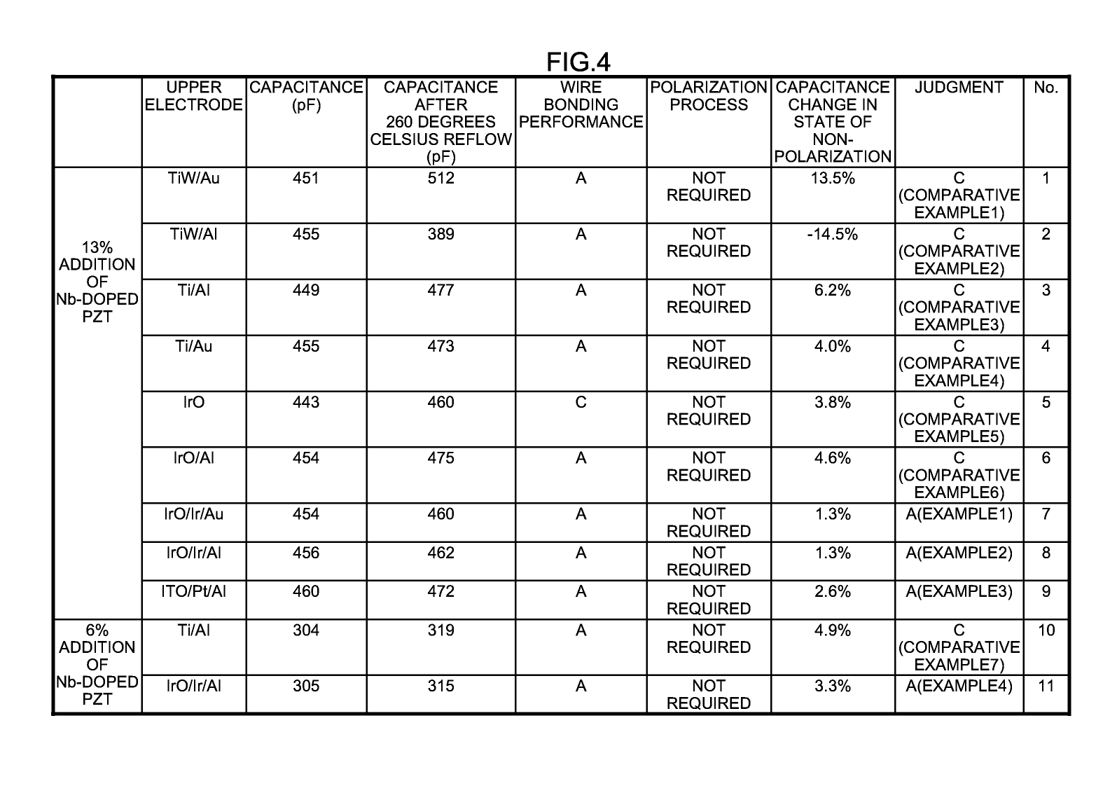

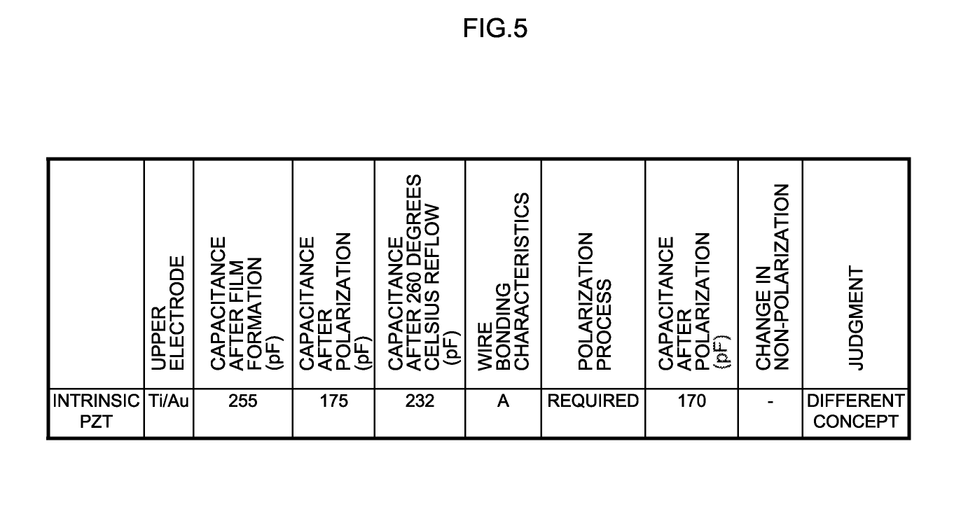

Next, Examples 1 to 4 and Comparative Examples 1 to 7 are described. FIG. 4 depicts conditions and evaluations of samples of Examples 1 to 4 and Comparative Examples 1 to 7. Sample Numbers 1 to 6 correspond to Comparative Examples 1 to 6, Sample Numbers 7 to 9 correspond to Examples 1 to 3, Sample Number 10 corresponds to Comparative Example 7, and Sample Number 11 corresponds to Example 4, respectively.

In Sample Numbers 1 to 9, Nb-doped PZT added with 13 at % Nb was used as a piezoelectric film, with the structure of the upper electrode varied. In Sample Numbers 10 and 11, Nb-doped PZT added with 6 at % Nb was used as a piezoelectric film, with the structure of the upper electrode varied. For each sample, a capacitance before reflow (a heating process) and a capacitance after reflow were measured to examine its change ratio. Also, wire bonding performance and whether a polarization process is required were also evaluated for each sample, and whether the device is good is determined from an all-around viewpoint.

In the table of FIG. 4, “A” is a sign representing an evaluation as excellent, and “C” represents an evaluation as faulty or inappropriate. In determining an all-around evaluation, “A” is determined when all of the following three conditions are satisfied: the wire bonding performance is evaluated as “A”; a polarization process is “not required”; and a change in capacitance is less than 4%.

Note that in the specification, in representation of the laminated structure of the film, the structure in which an A material layer, a B material layer, and a C material layer are sequentially laminated from a lower layer to an upper layer is represented by “A/B/C”. That is, a material indicated before “/” forms a lower layer and a material indicated after “/” forms an upper layer.

### Example 1

### Sample Number 7

As Example 1, a piezoelectric device was fabricated in the following procedure, and evaluations were made.

(Process 1)

A TiW film having a film thickness of 20 nm was formed by sputtering on a silicon (Si) wafer, and a Ir film having a film thickness of 150 nm was formed so as to be superposed of the TiW film (a lower electrode forming process). This laminated film of TiW (20 nm)/Ir (150 nm) serves as a lower electrode. Note that the material of the lower electrode and the film thickness of each layer are not restricted to the example above, and various designs can be made.

(Process 2)

Next, an Nb-doped PZT film (13 at % Nb addition amount) was formed on the lower electrode (a piezoelectric film forming process). In the present example, the film having a film thickness of 4 microns (μm) was formed by sputtering at a film formation temperature of 500° C. The Nb-doped PZT film is hereinafter referred to as an “Nb-PZT film” for convenience of description. To form the Nb-PZT film, high frequency (RF; radio frequency) magnetron sputtering device was used. As a film formation gas, a mixed gas of 97.5% Ar and 2.5% O₂ was used. As a target material, a material having a composition of Pb_{1.05} ((Zr_{0.52} Ti_{0.48})_{0.88}Nb_{0.12}) O₃ was used. The film formation pressure was 2.2 mTorr. Note that the amount of Nb in the obtained Nb-PZT film was 13 at %.

(Process 3)

Patterning for the upper electrode was formed on the Nb-PZT film by using a photoresist.

(Process 4)

Then, an Ir oxide (represented as “IrOₓ”, where x representing a composition ratio of Ir and O can take any value larger than 0, preferably 1 or more) serving as a first layer of the upper electrode was formed. In FIG. 4, this oxide is represented as “IrO” (an oxide metal layer forming process). IrOₓ (a reference numeral 5 in FIG. 1) was formed by reactive sputtering using an Ir target and by using a mixed gas of 50% Ar and 50% O₂ at a pressure of 0.5 Pa. Specifically, Ar was introduced at a flow rate of 10 ccm (cubic centimeter per minute) to form IrOₓ having a thickness of approximately 10 nm under the conditions of a film formation pressure of 0.5 Pa and an electric power of 600 W from high (radio) frequency (rf) power supply at room temperatures.

(Process 5)

Then, a gas of 100% Ar was used with the same target a slow rate of 10 ccm) to form Ir (a second layer of the upper electrode and a reference numeral 6 of FIG. 1) having a thickness of 20 nm at a pressure of 0.1 Pa (an oxidation-resistant metal layer forming process).

IrOₓ in Process 4 and Ir in Process 5 may be non-successively formed. More preferably, seamless film formation is performed by stopping (stopping the supply of) O₂ gas during IrOₓ film formation to gradually change the film from IrOₓ to Ir. As such, by successively eliminating oxygen during film formation, film formation can be seamlessly made. With this, IrOₓ/Ir with higher adhesive strength can be formed. In this film, oxygen (O) is gradually decreased from IrOₓ, and the film becomes Ir.

Note that the structure in which oxygen gas is stopped during metal oxide film formation to successively change the composition from the metal oxide to that metal for seamless film formation can be applied not restrictively to Ir but can be applied to another metal material.

(Process 6)

Next, Au (a third layer of the upper electrode and a reference numeral 7 of FIG. 1) having a thickness of 300 nm was formed on Ir with 100% Ar and a pressure of 0.1 Pa (a wire boning suitable metal layer forming process).

(Process 7)

A pattern of the upper electrode was fabricated by lifting off the obtained substrate.

(Process 8)

A capacitance was measured between the upper electrode (400 microns φ (diameter)) and the lower electrode of thus obtained substrate. Furthermore, an annealing process was performed in atmosphere at 260° C. Capacitances before and after reflow (actually, before and after the annealing process) were compared to calculate a change ratio. The sample of this Example 1 (Sample Number 7) has a good change ratio in capacitance of 1.3%.

(Process 9)

Next, wiring was performed by bonding using an Au wire and an Al wire. And, bonding suitability is examined. The sample of Example 1 (Sample Number 7) was excellent.

(Process 10)

Also, the state of Nb-PZT was in the state being polarized from that hysteresis characteristics.

### Example 2

### Sample Number 8

In Example 2, Al layer was formed in place of Au of the third layer in Example 1. The other conditions are similar to those in Example 1. As with Example 1, in this Example 2, a change in capacitance before and after reflow and wire bonding suitability were examined, and the results were excellent.

### Example 3

### Sample Number 9

In Example 3, ITO (Indium Tin Oxide or tin-doped indium oxide) was formed in place of IrOₓ of the first layer in Example 1. Then, Pt was formed as an oxygen blocking layer (the second layer), and Al was used as a metal layer suitable for wire bonding (the third layer). As with Example 1, in this sample (Sample Number 9), a change in capacitance before and after reflow and wire bonding suitability were examined, and excellent characteristics were exhibited.

### Example 4

### Sample Number 11

In Example 4, an Nb-PZT film was used with 6 at % Nb amount was used in place of the piezoelectric film in Example 1, and similar experiments were performed. As with Example 1, in the sample (Sample Number 11) of Example 4, a change in capacitance before and after reflow and wire bonding suitability were examined, and excellent characteristics were exhibited.

### Comparative Example 1

### Sample Number 1

As with Example 1, a substrate having a lower electrode and a Nb-PZT film (a thickness of 4 microns) with 13 at % Nb amount formed on a Si wafer was prepared, and TiW (20 nm) was formed as a first layer of an upper electrode and Au (300 nm) was formed as a second layer. In this sample (Sample Number 1), the capacitance was greatly changed before and after reflow at 260° C. (a change ratio of 13.5%). In the sample in which the capacitance of the sample is greatly changed, variations occur due to a temperature distribution of a heating process. Moreover, this can cause variations in performance of a device in use as a product, and therefore this sample is inappropriate. Note that the upper electrode in Comparative Example 1 using Nb-PZT is polarized even after the reflow process, and therefore no re-polarization process as required in a conventional device is not required.

### Comparative Examples 2 to 7

Similarly, regarding the upper electrode, samples were fabricated as Comparative Examples 2 to 7 (Sample Numbers 2 to 7), and evaluations were performed.

The samples having structured described in Comparative Examples 2 to 7 each have a capacitance after reflow significantly different from an initial value. This poses a problem in designing and also disadvantageously causes variations in characteristic due to variations in reflow temperature. Note that it has been found that this change in capacitance can be approximately returned to the original by applying a large voltage (applying a voltage on the order of 30 V to a piezoelectric film having a thickness of 4 microns) as in a polarization process.

Although the cause has not yet clearly been known, it is assumed that a subtle amount of oxygen is drawn from the piezoelectric substance to be moved to the electrode described above to change the capacitance.

Applying a high voltage as in a polarization process to return the change in capacitance after reflow to the original is extremely difficult in a product manufacturing process.

By contrast, as exemplarily described in Examples 1 to 4, according to the structure to which the presently disclosed subject matter is applied, the change in capacitance after reflow is small, and the device can be used in a good condition.

### Reference Example

Furthermore, as Reference Example, conditions and evaluation results of a sample using an intrinsic PZT. A sample according to this Reference Example is fabricated by forming Ti/Au as an upper electrode on an intrinsic PZT film not doped with Nb. As has been already described, the intrinsic PZT is required to be used after a polarization process, which makes processes complex. The intrinsic PZT is not polarized immediately after film formation and, by performing a polarization process, the capacitance has a constant value. However, through a reflow process, the capacitance again has a value close to a value immediately after film formation. The reason for this can be such that polarization in the film is partially eliminated by depolarization. In practice, by performing a polarization process again after reflow, the capacitance settles down to a constant value. From theses, the phenomenon in the intrinsic PZT and the phenomenon in Nb-PZT are totally different in concept.

The Nb-PZT is advantageous over the intrinsic PZT in that a polarization process is not required. However, even if Nb-PZT is used in place of the intrinsic PZT, the capacitance is significantly changed after reflow (a heating process) in the structure of the conventional upper electrode as illustrated in Comparative Examples 1 to 7. This problem is a new problem conventionally unknown, and its cause has not yet been known.

The inventors of the present application have paid attention to this new problem, examines the cause through experiments, and found that an electrode structure of inhibiting the movement of oxygen from the Nb-PZT film to the upper electrode is effective in solving the problem. By adopting the upper electrode exemplarily described in the above embodiment and Examples 1 to 4, a device can be used in a good condition with a small change in capacitance before and after reflow.

### Application Example

Next, a further specific example of a piezoelectric device is described.

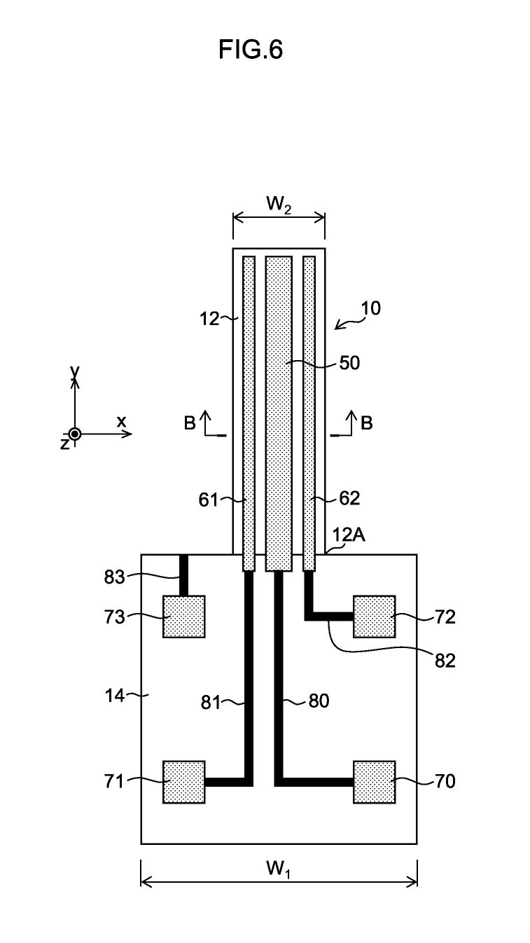

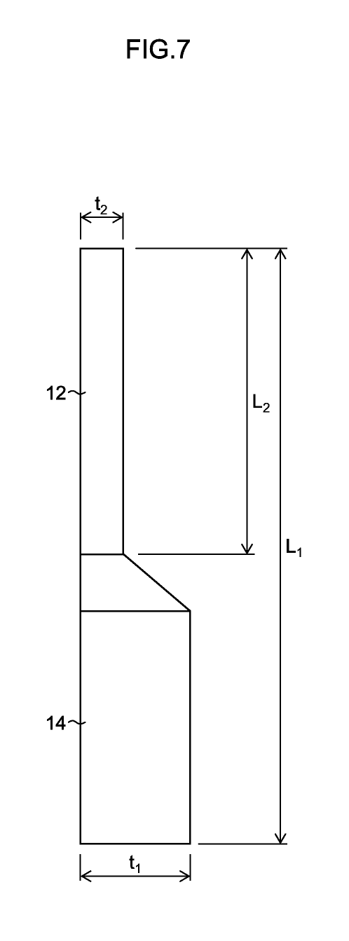

FIG. 6 is a plan view of an example of structure of the piezoelectric device according to the embodiment of the presently disclosed subject matter, and FIG. 7 is a side view thereof. Here, an angular velocity sensor is described by way of example as a specific example of a piezoelectric device. This angular velocity sensor 10 is a device to be mounted on a vibration-type gyro sensor. The angular velocity sensor 10 includes an arm part 12 and a base part 14 supporting the arm part 12. For convenience of description, in the plan view of FIG. 6, an x axis is introduced in a lateral (horizontal) direction on paper, a y axis is introduced in a longitudinal direction, and an orthogonal xyz axis of a z axis is introduced in a direction perpendicular to the paper.

The arm part 12 is provided so as to extend in a stick shape from the base part 14 along the y direction. The arm part 12 has its base end part 12A fixed to the base part 14, and functions as a vibrator of a so-called cantilever structure making a displacement with this fixed base end part 12A as a fixed end. The sensor shape with the arm part 12 extending from the base part 13 can be configured as, for example, an integrated structure cut out from a silicon (Si) monocrystalline substrate to a predetermined shape.

Note that the entire size and specific size are not particularly restrictive in implementing the invention.

Specific numerical values such as a thickness t1 of the base part 14, an overall length L1 of the device, a lateral width W1 of the base part 14, a length L2 of the arm part 12, and a thickness t2 of the arm part 12 can be designed as appropriate according to design specifications such as an element size of the product, a frequency for use, and others. By way of example, t1=300 μm, L1=3 mm, W1=1 mm, L2=2.5 mm, and t2=100 μm.

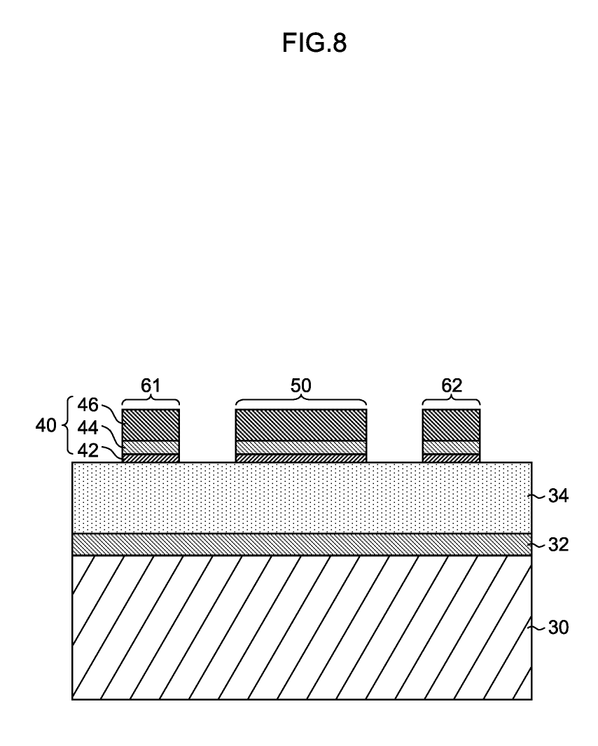

The arm part 12 is formed in a square pole having a substantially quadrangular sectional shape (for example, a rectangle or a square) when cut in a plane (an xz plane) perpendicular to the longitudinal direction (the y direction). A sectional view along a B-B line in FIG. 6 is depicted in FIG. 8. However, in FIG. 8, for convenience of description, the film thickness of each layer is drawn as being corrected as appropriate, the ratio of the film thicknesses do not necessarily reflect the actual film thicknesses.

The arm part 12 has a laminated structure in which a lower electrode 32, a piezoelectric film 34, and an upper electrode 40 are laminated in this order on a silicon layer 30 (corresponding to a “substrate”). The upper electrode 40 of this example has a multilayered structure in which an IrO layer 42 (corresponding to an “oxide electrode layer”), an Ir layer 44 (corresponding to a “first metal electrode layer”), and an Au layer 46 (corresponding to a “second metal electrode layer”) are sequentially laminated on the piezoelectric film 34. That is, the upper electrode 40 has a laminated structure of “IrO/Ir/Au”.

The silicon layer 30, the lower electrode 32, the piezoelectric film 34, and the upper electrode 40 of FIG. 8 correspond to the substrate 2, the lower electrode 3, the piezoelectric film 4, and the upper electrode 8 described in FIG. 1, respectively. The IrO layer 42, the Ir layer 44, and the Au layer 46 of FIG. 8 correspond to the oxide electrode layer 5, the first metal electrode layer 6, and the second metal electrode layer 7 of FIG. 1, respectively.

In the arm part 12 of FIG. 6, a drive electrode 50 and detection electrodes (61 and 62) are formed by isolation by patterning of the upper electrode 40. The drive electrode 50 and the detection electrodes (61 and 62) are formed in parallel along the longitudinal direction (the Y direction) so as to be isolated so that the detection electrodes (61 and 62) are not contact with each other. The detection electrodes (61 and 62) are placed on left and right sides across the drive electrode 50. The detection electrode denoted as the reference numeral 61 is referred to as a first detection electrode, and the detection electrode denoted as the reference numeral 62 is referred to as a second detection electrode. With the structure in which the piezoelectric film 34 is interposed between the drive electrode 50 and the lower electrode 32, an element for piezoelectric driving is formed. In this element for piezoelectric driving, the piezoelectric film 34 is deformed with application of a drive voltage between the electrodes, thereby vibrating the arm part 12. That is, the element for piezoelectric driving is a portion operating by using an inverse piezoelectric effect.

On the other hand, with the structure in which the piezoelectric film 34 is interposed between the first detection electrode 61 and the lower electrode 32, a first element for detection is formed. Also, with the structure in which the piezoelectric film 34 is interposed between the second detection electrode 62 and the lower electrode 32, a second element for detection is formed. These elements for detection detect a voltage occurring between the electrodes with deformation of the piezoelectric film 34. That is, the elements for detection are portions operating by using a piezoelectric effect.

The base part 14 is provided with terminals for external connection (pads 70 to 73) corresponding to the electrodes (50 to 52) and lead wires 80 to 83. The electrodes and the lead wires form an approximately bilaterally linear symmetric shape with respect to a center line parallel to the y axis passing through the center of the arm part 12 as a symmetry axis. Since the wiring pattern desirably has a symmetric shape as much as possible in view of residual stress, a dummy wire may be formed to increase the symmetric property of the wiring pattern.

The angular velocity sensor 10 as described above is connected to a drive detection circuit via the pads 70 to 73.

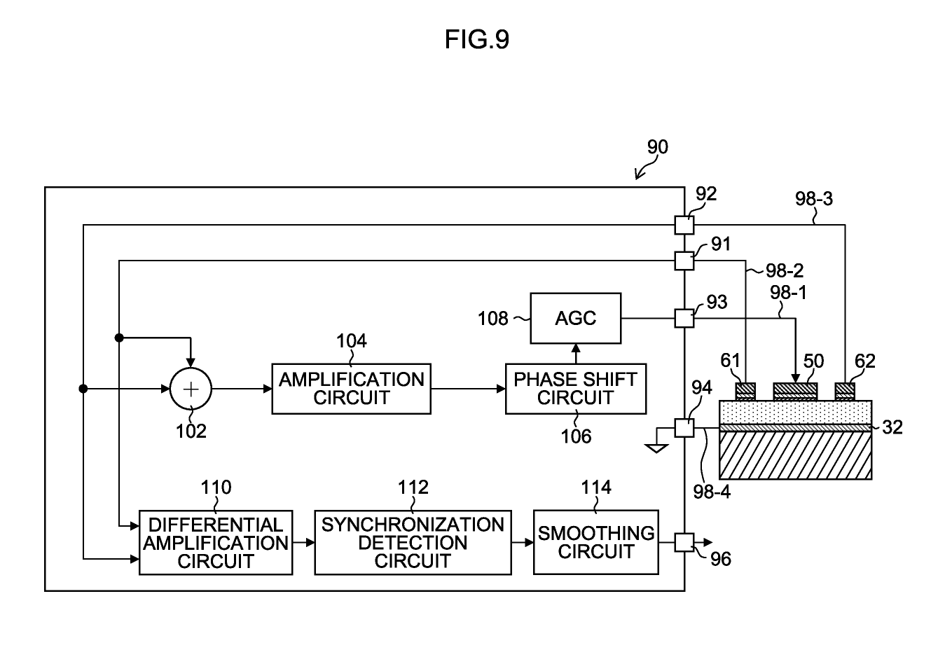

FIG. 9 is a block diagram of an example of structure of a drive detection circuit 90 (corresponding to an “electronic circuit”). The drive detection circuit 90 is configured of an ASIC. The drive detection circuit 90 has a first detection signal input terminal 91 connected to the first detection electrode 61 of the angular velocity sensor 10, a second detection signal input terminal 92 connected to the second detection electrode 62, a drive voltage output terminal 93 connected to the drive electrode 50, a common electrode terminal 94 connected to the lower electrode 32, and a sensor output terminal 96 for outputting a sensor signal.

The drive electrode 50, the first detection electrode 61, the second detection electrode 62, the lower electrode 32 are connected to corresponding terminals (91, 92, 93, and 94) via bonding wires 98-1, 98-2, 98-3, and 98-4, respectively.

The drive detection circuit 90 includes an addition circuit 102, an amplification circuit 104, a phase shift circuit 106, an AGC (auto gain controller) 108, a differential amplification circuit 110, a synchronization detection circuit 112, and a smoothing circuit 114. This circuit structure is disclosed in Japanese Patent Application Laid-Open No. 2008-157701. Signals inputted from the first detection signal input terminal 91 and the second detection signal input terminal 92 are both inputted to the addition circuit 102 and the differential amplification circuit 110.

With the addition circuit 102, the amplification circuit 104, the phase shift circuit 106, and the AGC 108 connected to the angular velocity sensor 10 via the terminals denoted by the reference numerals 91 to 94, a phase-shift-type oscillation circuit is configured.

A reference voltage is given to the common electrode terminal 94. By applying a voltage for piezoelectric driving (a drive voltage) between the lower electrode 32 and the drive electrode 50 via the drive voltage output terminal 93, the arm part 12 is vibrated in a self-induced manner. The vibrating direction of the arm part 12 at this time is a thickness direction of the arm part 12 (the z direction).

When the arm part 12 is vibrated in a self-induced manner, if an angular velocity occurs about the longitudinal direction (the y axis) of the arm part 12, the vibrating direction of the arm part 12 is changed by Coriolis force. With this change in vibrating direction, of a first detection signal (a signal obtained from the first detection electrode 61) and a second detection signal (a signal obtained from the second detection electrode 62), one of outputs is increased, and the other output is decreased. By inputting these signals to the differential amplification circuit 110 to detect a change amount of the signal amount, an angular velocity about the longitudinal direction (the y axis) can be detected. By the differential amplification circuit 110, the synchronization detection circuit 112, and the smoothing circuit 114, a detection circuit system for detecting an angular velocity of the arm part 12 (the vibrator) is configured.

FIG. 10 is a schematic view of the structure of a sensor device having the angular velocity sensor 10 and the ASIC packaged by being covered with a packaging member 130. The angular velocity sensor 10 is connected to the ASIC (the drive detection circuit 90) via a bonding wire 120. The bonding wire 120 in FIG. 10 corresponds to the components denoted as the reference numerals 98-1 to 98-4 in FIG. 4. Note that the electronic circuit to which the angular velocity sensor 10 is connected is not restricted to the ASIC (the drive detection circuit 90), and the angular velocity sensor 10 can be connected to a wiring member such as a lead frame. The package may be a ceramic package or a resin package, or may have another structure. Also, the structure of the package is not particularly restrictive. For example, the package may have a hollow structure therein, may be in a vacuum state as being hermetically sealed, or may have a structure as being sealed by being filled with insulating resin.

A sensor chip 140 having the angular velocity sensor 10 and the ASIC (the drive detection circuit 90) are integrally accommodated by the packaging member 130 as described above is configured as a sensor device. This sensor chip 140 is mounted on an electronic circuit board (for example, a glass epoxy resin circuit board) not illustrated, and is then completed as an electronic circuit board after a solder reflow process.

<Description of Manufacturing Method>

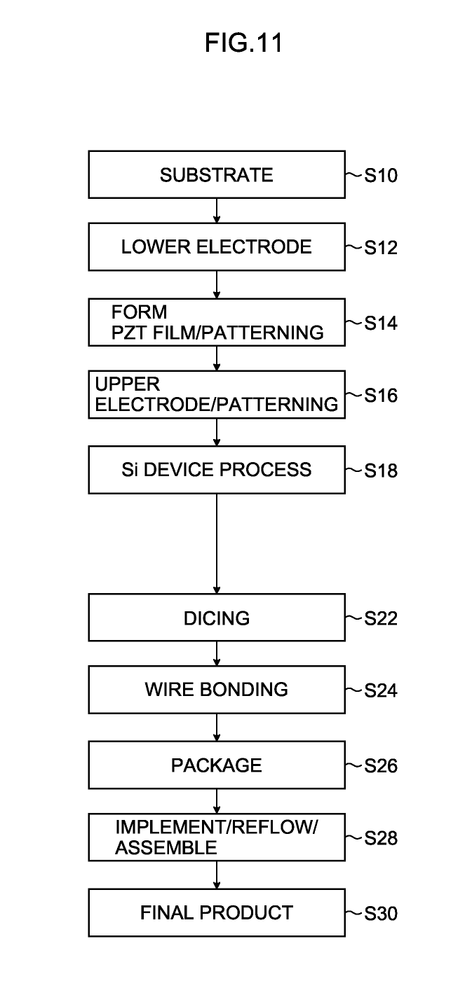

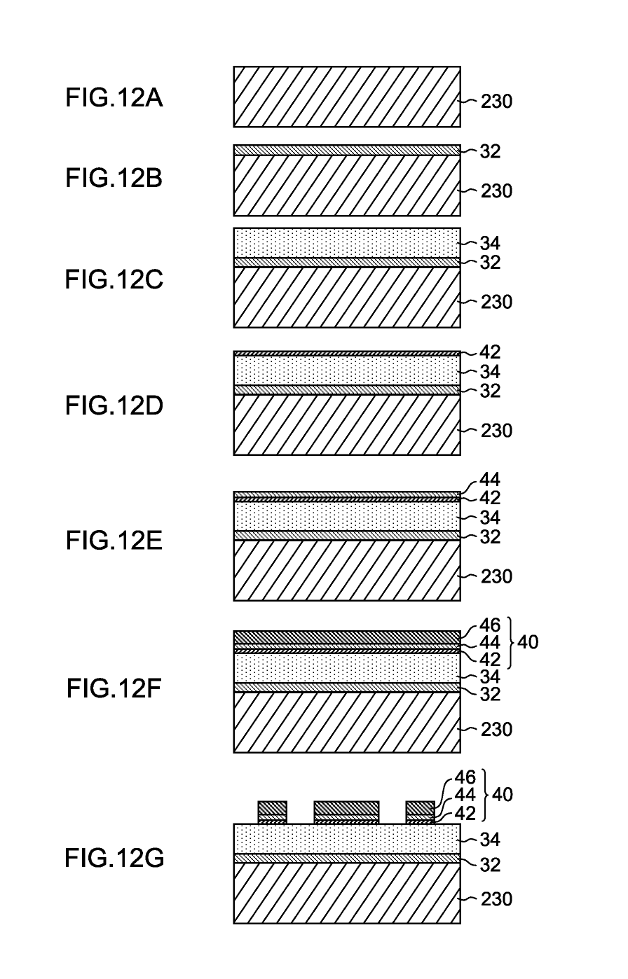

FIG. 11 is a flowchart of a process of manufacturing a piezoelectric device according to the present embodiment and an electronic device having the piezoelectric device mounted thereon. FIG. 12 is a diagram for describing a process of manufacturing the piezoelectric device. With reference to these drawings, the manufacturing method is described.

(Process 1)

First, a substrate 230 made of silicon (Si) is prepared (refer to step S10 in FIG. 11 and FIG. 12A). While an example is described herein in which a monocrystalline bulk silicon substrate (a Si wafer) is used, a SOI (Silicon On Insulator) substrate may be used. The substrate 230 is a portion that will serve as the silicon layer 30 described with reference to FIG. 3.

(Process 2)

Next, a lower electrode 32 is formed on one side surface (an upper surface in FIG. 12A) of the substrate 230 (refer to step S12 in FIG. 11 and FIG. 12B). In the present example, a TiW film having a film thickness of 20 nm was formed by sputtering, and then an Ir film having a film thickness of 150 nm was formed so as to be superposed thereon. This TiW (20 nm)/Ir (150 nm) laminated film serves as the lower electrode 32. Note that the material of the lower electrode 32 and the film thickness of each layer are not restricted to the example described above, and various designs can be taken.

(Process 3)

Then, an Nb-doped PZT film (the piezoelectric film 34) is formed on the lower electrode 32, and patterning is performed to a desired shape (refer to step S14 in FIG. 11 and FIG. 12C). In the present example, an Nb-doped PZT thin film (denoted as the reference numeral 34) having a film thickness of 4 μm was formed on the lower electrode 32 by sputtering at a film formation temperature of 500° C. Specific film formation conditions are as described in Example 1.

(Process 4)

Furthermore, the upper electrode 40 is formed on this PZT thin film, and patterning is performed to a desired shape (step S16 in FIG. 11 and FIGS. 12D-12G). The upper electrode 40 in this example has a laminated structure of IrO/Ir/Au. A specific film forming method is as described in Example 1.

(Process 5)

Then, the Si substrate 230 is processed so as to have a desired shape and thickness (step S18, “Si device processing process”).

(Process 6)

Then, the wafer is isolated into individual element units by dicing (step S22, “dicing process”).

(Process 7)

Next, an electrical connection of the element obtained by individual isolation to an integrated circuit is performed (step S24, “wire bonding process”).

(Process 8)

Then, device packaging is performed with a packaging material (step S26, “packaging process”). With this, a packaged sensor device is obtained.

(Process 9)

The packaged device is implemented on an electronic circuit substrate “implementing process”), and a reflow process is performed (“reflow process”, step S28). Reflow is a known technology as an implementation technology, and is a process in which, when an electronic component is implemented on a circuit board such as a printed board, the electronic component is mounted in advance on a substrate coated with solder paste and is heated for collective bonding. As a matter of course, not only the device in this example but also other various electronic components can be implemented on an electronic circuit board, and each electronic component is fixed (soldered bonding) to the electronic circuit board. In this manner, an electronic circuit board having devices mounted thereon is fabricated. Then, the electronic circuit board is assembled in an electronic device assembling process (step S28), thereby manufacturing a final product (an electronic device) (step S30).

Examples of the electronic device herein can include various devices, such as a portable phone, a digital camera, a personal computer, a digital music player, a game machine, and a medical device such as an electronic endoscope, and the target device is not particularly restrictive.

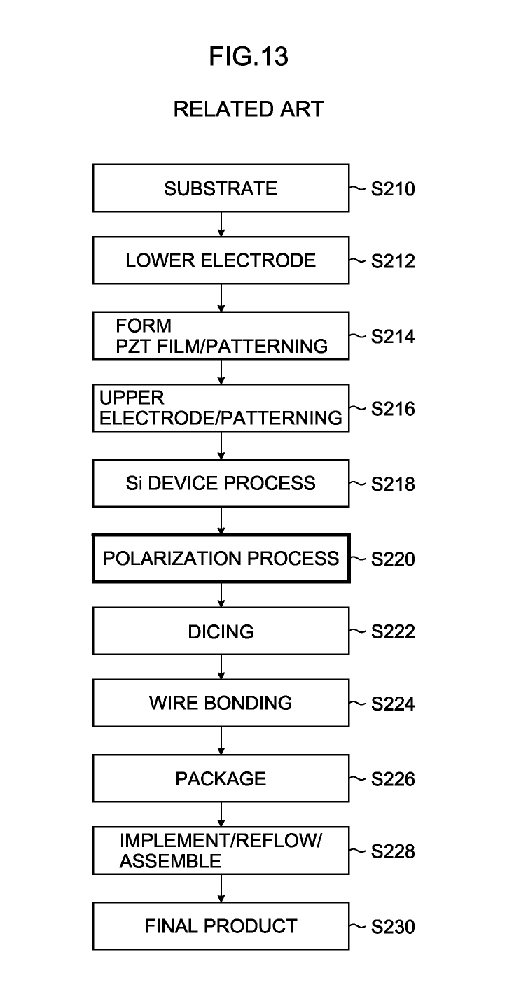

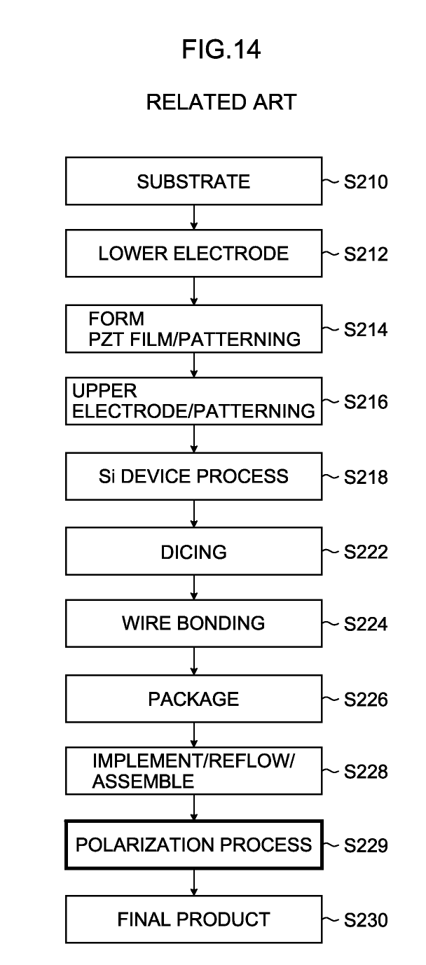

As is evident when the process flow depicted in FIG. 11 and the conventional process flow depicted in FIG. 13 and FIG. 14 are compared with each other, the “polarization process” is omitted in the process flow according to the present embodiment (FIG. 11).

According to the present embodiment, with adoption of the Nb-doped PZT film, the conventional polarization process is not required. Also, according to the present embodiment, changes in capacitance after reflow can be suppressed, and a re-polarization process is not required, either. According to the present embodiment, since the piezoelectric performance is not degraded by reflow, variations in device performance can be suppressed, and stability of sensor performance can be ensured. For this reason, compared with the conventional structure, the accuracy of the sensor is increased, and the use purposes of the sensor are also widened.

### Modification Example 1

The angular velocity sensor is not restricted to the one illustrated in FIG. 6, and can be configured as the one having a plurality of arm parts as described in Japanese Patent Application Laid-Open No. 2009-244202. Also, the sensor is not restricted to the one using an actuator for driving (using an inverse piezoelectric effect) and a piezoelectric substance (using a piezoelectric effect), and the presently disclosed subject matter can also be applied to a sensor element using only the piezoelectric effect and an actuator element using only the inverse piezoelectric effect.

The presently disclosed subject matter can be used for various use purposes as an angular velocity sensor, an acceleration sensor, a pressure sensor, an actuator, a power generator, or others and, in particular, achieves effects in sensing a fine voltage drive region or a fine voltage.

### Modification Example 2

While reflow has been described as a heating process in the above embodiment, other heating processes other than reflow, such as high-temperature burning, can be similarly supported.

### Modification Example 3

While an Nb-doped PZT film has been exemplarily described in the above embodiment, the presently disclosed subject matter can also be applied to a PZT film doped with at least one type of metal element X selected from element groups of the V group and the VI group, based on a similar problem-solving principle of inhibiting the movement of oxygen between the piezoelectric film and the upper electrode.

Also, various materials can be selected as a material of each layer of the oxide electrode layer 5, the first metal electrode layer 6, and the second metal electrode layer 7 included in the upper electrode 8, in a range of achieving each role for the purpose of each layer.

Note that the presently disclosed subject matter is not restricted to the embodiments described above, and can be variously modified by a person who has common knowledge in the field within the technical ideas of the presently disclosed subject matter.

<Various Aspects of the Disclosed Invention>

As can be understood from the detailed description of the embodiments above, the specification includes disclosure of various technical ideas including aspects of the invention as described below.

(First Aspect)

A piezoelectric device includes: a substrate, a lower electrode provided on a substrate, a piezoelectric film provided by being laminated on the lower electrode, the piezoelectric film being formed of lead zirconate titanate (PZT) containing 6 at % or more in atomic composition percentage of at least one type of metal element selected from the V group and the VI group, an oxide electrode layer provided by being laminated on the piezoelectric film, a first metal electrode layer containing an oxidation-resistant precious metal provided by being laminated on the oxide electrode layer, a second metal electrode layer provided by being laminated on the first metal electrode layer, and a wire connected to the second metal electrode layer by wire bonding, and the piezoelectric device operates by using at least one of a piezoelectric effect and an inverse piezoelectric effect of the piezoelectric film.

According to this aspect, the piezoelectric device has a laminated structure formed by sequentially laminating, from a side near a substrate surface, the lower electrode, the piezoelectric film, the oxide electrode layer, the first metal electrode layer, and the second metal electrode layer on the substrate. With the laminated structure of the oxide electrode layer, the first metal electrode layer, and the second metal electrode layer, an upper electrode is configured. With the structure in which the piezoelectric film is interposed between the upper electrode and the lower electrode, a piezoelectric element operating by using at least one of the piezoelectric effect and the inverse piezoelectric effect of the piezoelectric film.

The oxide electrode layer plays a role of preventing oxygen from being drawn from the piezoelectric film, and also functions as an adhesive layer increasing adhesiveness between the piezoelectric film and the upper electrode.

The first metal electrode functions as an oxygen blocking layer inhibiting the movement of oxygen from the piezoelectric film to the second metal electrode layer. With this, a change in composition of the piezoelectric film, a change in structure of the upper electrode, and a decrease in adhesiveness are prevented, and a change in capacitance after heating such as reflow can be inhibited.

Since the second metal electrode is to be connected to an electronic circuit by wire bonding, a material in consideration of affinity (wire bonding performance) with a wire is used.

According to this aspect, a piezoelectric device with a small change in capacitance (a small degradation in piezoelectric performance) even with heating and without requiring a polarization process can be achieved. Also, the piezoelectric film for use in this aspect has an excellent piezoelectric characteristic, and can be used for various purposes operating with piezoelectric displacement (deformation), such as an actuator, a sensor, an electric power generator.

(Second Aspect)

In the piezoelectric device according to the first aspect, the piezoelectric film can be configured to be an Nb-doped PZT film containing 6 at % or more of Nb as the metal element.

(Third Aspect)

In the piezoelectric device according to the second aspect, the piezoelectric film can be formed by chemical vapor deposition.

The Nb-doped PZT film formed by chemical vapor deposition is in a state already polarized at the time of film formation, and a polarization process, which is required for conventional intrinsic PZT, is not required.

(Fourth Aspect)

In the piezoelectric device according to any one of the first to third aspects, the oxide electrode layer can be configured to be made of any one of ITO, LaNiO, IrOₓ, RuOₓ, and PtOₓ (where x representing a composition ratio is any number equal to 1 or more).

(Fifth Aspect)

In the piezoelectric device according to any one of the first to fourth aspects, the first metal electrode layer can be configured to contain any one of Ir, Pt, Ru, and Pd.

(Sixth Aspect)

In the piezoelectric device according to any one of the first to fifth aspects, the second metal electrode layer can be configured to contain any one of Al, Au, Ti, Cu, Cr, and Ni.

Since a general bonding wire is made of Au, Cu, Al, or the like, when bondability with any of these wires is considered, any one of Al, Au, Ti, Cu, Cr, and Ni is preferably used as the second metal electrode layer.

(Seventh Aspect)

In the piezoelectric device according to any one of the first to sixth aspects, the oxide electrode layer and the first metal electrode layer can be configured to contain a same metal element.

(Eighth Aspect)

In the piezoelectric device according to the seventh aspect, the oxide electrode layer and the first metal electrode layer can be configured to be seamlessly formed.

According to this aspect, adhesiveness is further reinforced.

(Ninth Aspect)

The piezoelectric device according to any one of the first to eighth aspects can be configured to further include an electronic circuit connected via the wire to the piezoelectric device, and the piezoelectric device and the electronic circuit can be configured to be packaged by a packaging material.

According to this aspect, a piezoelectric device less prone to be influenced by a heating process such as reflow and stable in device performance can be provided.

(Tenth Aspect)

A piezoelectric device manufacturing method includes: a lower electrode forming step of forming a lower electrode on a substrate, a piezoelectric film forming step of laminating a piezoelectric film on the lower electrode, the piezoelectric film being formed of lead zirconate titanate (PZT) containing 6 at % or more in atomic composition percentage of at least one type of metal element selected from the V group and the VI group, an oxide electrode layer forming step of laminating an oxide electrode layer on the piezoelectric film, a first metal electrode layer forming step of forming a first metal electrode layer containing an oxidation-resistant precious metal on the oxide electrode layer, a second metal electrode layer forming step of laminating a second metal electrode layer on the first metal electrode layer, and a wire bonding step of connecting the second metal electrode layer to an electronic circuit by wire bonding, and a piezoelectric device operating by using at least one of a piezoelectric effect and an inverse piezoelectric effect of the piezoelectric film is manufactured.

(Eleventh Aspect)

The piezoelectric device manufacturing method according to the tenth aspect can be configured to further include, after the wire bonding, a packaging step of packaging the piezoelectric device and the electronic circuit by using a packaging material.

(Twelfth Aspect)

An electronic device manufacturing method includes each step of the piezoelectric device manufacturing method according to claim 10 or 11, a reflow step of implementing the piezoelectric device manufactured by the piezoelectric device manufacturing method on an electronic circuit board and performing solder bonding, and manufacturing an electronic device having the electronic circuit board after the reflow step incorporated therein, without performing a polarization process on the piezoelectric film before and after the reflow process.

What is claimed is:

1. A piezoelectric device comprising:
a substrate;
a lower electrode provided on a substrate;
a piezoelectric film provided by being laminated on the lower electrode, the piezoelectric film being formed of lead zirconate titanate (PZT) containing 6 at % or more in atomic composition percentage of at least one type of metal element selected from V group and VI group;
an oxide electrode layer provided by being laminated on the piezoelectric film;
a first metal electrode layer containing an oxidation-resistant precious metal provided by being laminated on the oxide electrode layer;
a second metal electrode layer provided by being laminated on the first metal electrode layer; and
a wire connected to the second metal electrode layer by wire bonding, wherein
the piezoelectric device operates by using at least one of a piezoelectric effect and an inverse piezoelectric effect of the piezoelectric film.

2. The piezoelectric device according to claim 1, wherein
the piezoelectric film is an Nb-doped PZT film containing 6 at % or more of Nb as the metal element.

3. The piezoelectric device according to claim 2, wherein
the piezoelectric film is formed by chemical vapor deposition.

4. The piezoelectric device according to claim 1, wherein
the oxide electrode layer is made of any one of ITO, LaNiO, IrOₓ, RuOₓ, and PtOₓ (where x representing a composition ratio is any number equal to 1 or more).

5. The piezoelectric device according to claim 1, wherein
the first metal electrode layer contains any one of Ir, Pt, Ru, and Pd.

6. The piezoelectric device according to claim 1, wherein
the second metal electrode layer contains any one of Al, Au, Ti, Cu, Cr, and Ni.

7. The piezoelectric device according to claim 1, wherein
the oxide electrode layer and the first metal electrode layer contain a same metal element.

8. The piezoelectric device according to claim 7, wherein
the oxide electrode layer and the first metal electrode layer are seamlessly formed.

9. The piezoelectric device according to claim 1, further comprising an electronic circuit connected via the wire to the piezoelectric device, wherein
the piezoelectric device and the electronic circuit are packaged by a packaging material.

10. A piezoelectric device manufacturing method comprising:
a lower electrode forming step of forming a lower electrode on a substrate;
a piezoelectric film forming step of laminating a piezoelectric film on the lower electrode, the piezoelectric film being formed of lead zirconate titanate (PZT) containing 6 at % or more in atomic composition percentage of at least one type of metal element selected from V group and VI group;
an oxide electrode layer forming step of laminating an oxide electrode layer on the piezoelectric film;
a first metal electrode layer forming step of forming a first metal electrode layer containing an oxidation-resistant precious metal on the oxide electrode layer;
a second metal electrode layer forming step of laminating a second metal electrode layer on the first metal electrode layer; and
a wire bonding step of connecting the second metal electrode layer to an electronic circuit by wire bonding, wherein
a piezoelectric device operating by using at least one of a piezoelectric effect and an inverse piezoelectric effect of the piezoelectric film is manufactured.

11. The piezoelectric device manufacturing method according to claim 10, further comprising, after the wire bonding step, a packaging step of packaging the piezoelectric device and the electronic circuit by using a packaging material.

12. An electronic device manufacturing method comprising:
each step of the piezoelectric device manufacturing method according to claim 10;
a reflow step of implementing the piezoelectric device manufactured by the piezoelectric device manufacturing method on an electronic circuit board and performing solder bonding; and
manufacturing an electronic device having the electronic circuit board after the reflow step incorporated therein, without performing a polarization process on the piezoelectric film before and after the reflow process.
